(19) United States
(12) Patent Application Publication
(10) Pub. No.: US 2024/0339478 A1
(43) Pub. Date: Oct. 10, 2024

(54) IMAGE SENSOR

(71) Applicant: Commissariat à I'Énergie Atomique et aux Énergies Alternatives, Paris (FR)

(72) Inventors: Olivier Saxod, Grenoble Cedex 9 (FR); François Ayel, Grenoble Cedex 9 (FR)

(73) Assignee: Commissariat à I'Énergie Atomique et aux Énergies Alternatives, Paris (FR)

(21) Appl. No.: 18/579,322

(22) PCT Filed: Jul. 20, 2022
(86) PCT No.: PCT/EP2022/070288

§ 371 Date: Jan. 12, 2024

(30) Foreign Application Priority Data
Jul. 28, 2021 (FR) FR2108202

(51) Int. Cl. H01L 27/146

(52) U.S. Cl. CPC H01L 27/14638; H01L 27/14603; H01L 27/1461; H01L 27/14636

(57) ABSTRACT

An image sensor including a plurality of pixels formed inside and on top of a semiconductor substrate, each pixel including: a photosensitive area formed in the semiconductor substrate; a peripheral insulating trench vertically extending across the substrate, from an upper surface of the substrate, and laterally delimiting the photosensitive area; a charge collection area; a transfer region located in the substrate and vertically extending between the charge collection area and the photosensitive area; and a transfer gate vertically extending across the substrate, from the upper surface of the substrate, deeper than the charge collection area, wherein the charge collection area laterally extends from the transfer gate all the way to the peripheral insulating trench.

The present application claims priority of French patent application 21/08202 which is incorporated herein by reference to the extent authorized by law.

### TECHNICAL FIELD

The present disclosure generally concerns electronic devices. The present disclosure more particularly concerns image sensor pixels.

### PRIOR ART

Image sensor pixels, each comprising a photosensitive area formed inside and on top of a semiconductor substrate, adapted to converting incident light into electron-hole pairs, are known. During an exposure phase, photogenerated charges (electrons or holes) accumulate in the photosensitive area. During a subsequent readout phase, a charge transfer device is controlled to transfer the photogenerated charges accumulated in the photosensitive area to a charge collection area.

It would be desirable to improve existing image sensor pixels. In particular, it would be desirable to be able to decrease the dimensions of such pixels, to enable the forming of image sensors having pixel pitches smaller than those of current sensors.

### SUMMARY

There exists a need to overcome all or part of the disadvantages of known image sensor pixels.

An embodiment overcomes all or part of the disadvantages of known image sensor pixels.

An embodiment provides an image sensor comprising a plurality of pixels formed inside and on top of a semiconductor substrate, each pixel comprising:
a photosensitive area formed in the semiconductor substrate;
a peripheral insulating trench vertically extending across the semiconductor substrate, from an upper surface of the semiconductor substrate, and laterally delimiting the photosensitive area;
a charge collection area;
a transfer region located in the semiconductor substrate and vertically extending between the charge collection area and the photosensitive area; and
a transfer gate vertically extending across the semiconductor substrate, from the upper surface of the semiconductor substrate, deeper than the charge collection area, wherein the charge collection area laterally extends from the transfer gate all the way to the peripheral insulating trench.

According to an embodiment, the charge collection area has a same conductivity type and a higher doping level than the transfer region.

According to an embodiment, the transfer region has a same conductivity type and a same doping level as the photosensitive area.

According to an embodiment, the transfer gate of each pixel has, in top view, a U shape.

According to an embodiment, the transfer gate of each pixel has, in top view, an L shape.

According to an embodiment, the transfer gate of each pixel has, in top view, an I shape.

According to an embodiment, the transfer gate of each pixel comprises a capacitive insulating trench comprising an electrically-conductive region insulated from the semiconductor substrate.

According to an embodiment, the electrically-conductive region is made of a metal or of a metal alloy.

According to an embodiment, the electrically-conductive region is made of polysilicon.

According to an embodiment, the transfer gate is separated from the peripheral insulating trench by a non-zero distance.

According to an embodiment, the sensor further comprises a conductive pad located on top of and in contact with the charge collection area, at a distance from the transfer gate and from the peripheral insulating trench.

According to an embodiment, the charge collection area and the conductive pad are shared between two neighboring pixels.

According to an embodiment, the charge collection area and the conductive pad are shared between four neighboring pixels.

According to an embodiment, the transfer gate has, in top view, an I shape, the transfer gates of two diagonally-opposite pixels being parallel to each other.

According to an embodiment, the peripheral insulating trench comprises a conductive region insulated from the substrate.

According to an embodiment, the sensor further comprises a control circuit configured to alternately apply, to the transfer gate:
a first potential adapted to blocking a charge transfer from the photosensitive area to the charge collection area; and
a second potential, different from the first potential, adapted to allowing a charge transfer from the photosensitive area to the charge collection area.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a simplified and partial top view of an example of an image sensor pixel;

FIG. 2 is a simplified and partial cross-section view of the pixel of FIG. 1 along plane AA of FIG. 1;

FIG. 3 is a simplified and partial top view of an example of a pixel of an image sensor according to a first embodiment;

FIG. 4 is a simplified and partial cross-section view of the pixel of FIG. 3 along plane BB of FIG. 3;

FIG. 5 is a simplified and partial top view of an example of a pixel of an image sensor according to a second embodiment;

FIG. 6 is a simplified and partial top view of a variant of the pixel of FIG. 5;

FIG. 7 is a simplified and partial top view of an example of a pixel of an image sensor according to a third embodiment;

FIG. 8 is a simplified and partial top view of an arrangement of two pixels according to the first embodiment;

FIG. 9 is a simplified and partial top view of an arrangement of four pixels according to the second embodiment;

FIG. 10 is a simplified and partial top view of an arrangement of two pixels according to the third embodiment;

FIG. 11 is a simplified and partial top view of an arrangement of two pixels according to the variant of FIG. 6;

FIG. 12 is a simplified and partial top view of a variant of the pixel of FIG. 7; and

FIG. 13 is a simplified and partial top view of an arrangement of four pixels according to the variant of FIG. 12.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, the methods of image sensor pixel manufacturing have not been detailed, the described embodiments and variants being compatible with usual image sensor pixel manufacturing methods. Further, the circuits (transistors and connections) of the pixels have not been detailed, the described embodiments and variants being compatible with usual pixel circuits. Further, the readout circuits, or column decoders, the control circuits, or row decoders, and the applications where image sensors may be provided have not been detailed, the described embodiments and variants being compatible with the readout circuits and the control circuits of usual image sensors, as well as with usual applications implementing image sensors.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

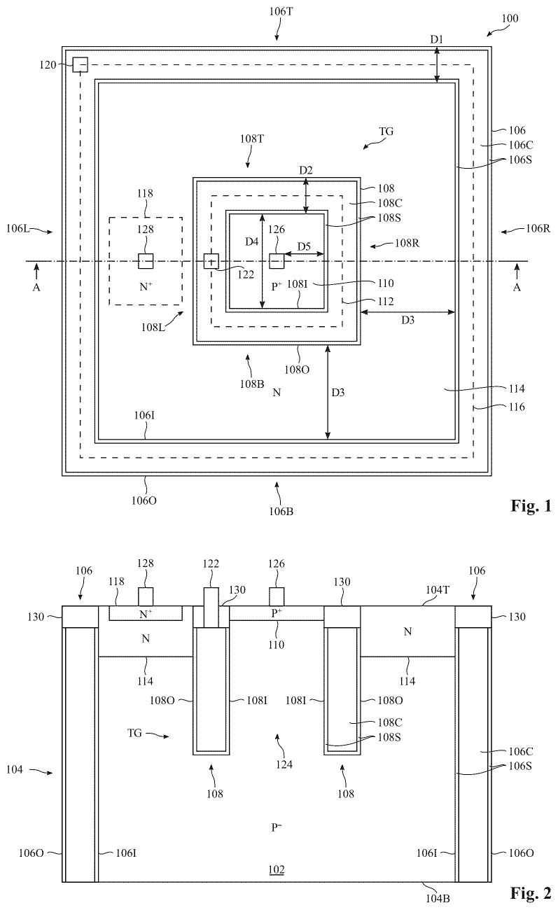

FIG. 1 is a partial and simplified top view of an example of an image sensor pixel 100. FIG. 2 is a partial and simplified cross-section view of pixel 100 along plane AA of FIG. 1.

In the shown example, pixel 100 comprises a photosensitive area 102, or photoconversion area. Photosensitive area 102 is designed, for example, to collect photons during illumination phases of the image sensor to which the pixel 100 belongs, and to convert these photons into electron-hole pairs. In top view, photosensitive area 102 is located at the center of pixel 100 and has a substantially square-shaped periphery.

Photosensitive area 102 is for example formed in a substrate 104. As an example, substrate 104 is a wafer or a piece of wafer made of a doped semiconductor material of a first conductivity type, for example of lightly-doped P-type silicon (P⁻). Substrate 104 for example has, in a region having photosensitive area 102 formed therein, a doping rate in the range from 1×10¹⁰ to 1×10¹⁷ at./cm³. As an example, substrate 104 has a thickness in the range from 1 to 20 μm.

Photosensitive area 102 is for example intended to be illuminated from a lower surface 104B of substrate 104. Although this has not been illustrated in FIG. 2, the lower surface 104B of substrate 104 may in this case be coated with one or a plurality of passivation layers. On the side of the lower surface 104B of substrate 104, pixel 100 may further comprise optical elements such as a filter, for example a color filter, and/or a microlens.

In the shown example, pixel 100 comprises a peripheral insulating trench 106, for example a capacitive insulating trench, laterally delimiting photosensitive area 102. In top view, peripheral insulating trench 106 totally surrounds photosensitive area 102 and for example has a substantially square-shaped contour. In the shown example, peripheral insulating trench 106 comprises four parts 106T, 106L, 106B, and 106R. Sections 106T and 106B are parallel to each other and orthogonal to sections 106L and 106R, section 106R being parallel to section 106L.

In particular, peripheral insulating trench 106 electrically insulates the photosensitive area 102 of pixel 100 from the photosensitive areas of neighboring pixels, not shown in FIGS. 1 and 2. Peripheral insulating trench 106 is for example formed in substrate 104. In the orientation of FIG. 2, peripheral insulating trench 106 for example extends vertically across the thickness of substrate 104, from an upper surface 104T of substrate 104, to the lower surface 104B of substrate 104. In other words, peripheral insulating trench 106 extends vertically, in this example, across the entire thickness of substrate 104 and emerges onto the side of lower surface 104B.

In the shown example, peripheral insulating trench 106 has inner side walls 106I, located on the side of the center of pixel 100, and outer side walls 106O, opposite to inner side walls 106I. The outer side walls 106O of peripheral insulating trench 106, for example, delimit an outer perimeter of pixel 100.

Peripheral insulating trench 106 for example has a width D1 in the range from 20 to 300 nm, and a depth in the range from 1 to 20 μm. In the example illustrated in FIG. 2, peripheral insulating trench 106 has a depth equal to the thickness of substrate 104.

In the shown example, peripheral insulating trench 106 comprises an electrically-conductive region 106C. As an example, electrically-conductive region 106C is made of polysilicon, of a metal, for example, copper, or of a metal alloy.

Peripheral insulating trench 106 further comprises, in this example, an electrically-insulating layer 106S coating the side walls of electrically-conductive region 106C. Electrically-insulating layer 106S electrically insulates electrically-conductive region 106C from substrate 104. As an example, electrically-insulating layer 106S is made of a dielectric material, for example, silicon oxide.

In the shown example, pixel 100 further comprises a vertical transfer gate TG formed in semiconductor substrate 104. Vertical transfer gate TG is for example located, in top view, in a central part of pixel 100, inside of the part of substrate 104 delimited by peripheral insulating trench 106.

Vertical transfer gate TG for example comprises an insulating trench 108 vertically extending across the thickness of substrate 104, from its upper surface 104T, down to a depth smaller than that of peripheral insulating trench 106. Insulating trench 108 is interrupted in the thickness of substrate 104 and does not emerge onto the side of the lower surface 104B of substrate 104. As an example, insulating trench 108 has a depth in the range from 0.2 to 1.5 μm.

The insulating trench 108 of vertical transfer gate TG has, in top view, a ring shape. The insulating trench 108 of vertical transfer gate TG for example has, in top view, a substantially square-shaped contour. In the shown example, insulating trench 108 more precisely has four parts 108T, 108L, 108B, and 108R. Parts 108T and 108B are parallel to each other and orthogonal to parts 108L and 108R, part 108R being parallel to part 108L. Further, in this example, the parts 108T, 108L, 108B, and 108R of trench 108 are respectively parallel to the parts 106T, 106L, 106B, and 106R of trench 106.

In the shown example, insulating trench 108 has inner side walls 108I, located on the side of the center of pixel 100, and outer side walls 1080, opposite to the inner side walls 108I and located in front of the inner side walls 106I of peripheral insulating trench 106. In the example illustrated in FIGS. 1 and 2, the outer and inner side walls 1080 and 108I of insulating trench 108 respectively correspond to the outer and inner side walls of vertical transfer gate TG.

The insulating trench 108 of vertical transfer gate TG for example has a width D2 substantially equal to the width D1 of peripheral insulating trench 106. Width D2 is for example in the range from 20 to 300 nm.

In the shown example, the insulating trench 108 of vertical transfer gate TG has a structure similar to that of peripheral insulating trench 106. More precisely, in this example, insulating trench 108 comprises an electrically-conductive region 108C made of polysilicon, of a metal, for example, copper, or of a metal alloy. The electrically-conductive region 108C of insulating trench 108 is, for example, made of the same material as the electrically-conductive region 106C of peripheral insulating trench 106.

The insulating trench 108 of vertical gate TG further comprises, in this example, an electrically-insulating layer 108S coating the side walls and the lower surface of electrically-conductive region 108C. Electrically-insulating layer 108S electrically insulates electrically-conductive region 108C from substrate 104. As an example, electrically-insulating layer 108S is made of a dielectric material, for example of silicon oxide. The electrically-insulating region 108S of insulating trench 108 is, for example, made of the same material as the electrically-insulating region 106S of peripheral insulating trench 106.

In the example illustrated in FIGS. 1 and 2, vertical transfer gate TG is centered with respect to peripheral insulating trench 106. In this example, each part 108T, 108L, 108B, 108R is separated from the nearest part 106T, 106L, 106B, 106R by the same distance D3, to within manufacturing dispersions. As an example, distance D3 is in the range from 20 to 300 nm.

In the shown example, the inner side walls 108I of vertical transfer gate TG laterally delimit a charge collection area 110. In the shown example, charge collection area 110 vertically extends across the thickness of substrate 104, from its upper surface 104T, and is bordered on all its side walls by insulating trench 108. Charge collection area 110 is, for example, more heavily doped with the first conductivity type, type P in this example (P⁺), than photosensitive area 102. Substrate 104 for example has, at the location where charge collection area 110 is formed, a doping level in the range from 1×10¹⁶ to 5×10²⁰ at./cm³.

As an example, charge collection area 110 has, in top view, a substantially square shape with a side length D4. In other words, each inner side wall 108I of insulating trench 108 is separated from the opposite inner side wall 108I by distance D4. Distance D4 is, for example, in the range from 50 to 500 nm.

Charge collection area 110 vertically extends across substrate 104, from its upper surface 104T, down to a depth smaller than that of the insulating trench 108 of vertical transfer gate TG.

As an example, charge collection area 110 is formed by ion implantation of doping species on the side of the upper surface 104T of substrate 104 in a region symbolized, in FIG. 1, by a dotted frame 112.

In the shown example, pixel 100 further comprises a well 114 laterally interposed between peripheral insulating trench 106 and vertical transfer gate TG. Well 114 vertically extends across the thickness of substrate 104, from its upper face 104T, between peripheral insulating trench 106 and the insulating trench 108 of vertical transfer gate TG. In the shown example, well 114 is laterally delimited by the inner side walls 106I of peripheral insulating trench 106 and by the outer side walls 1080 of insulating trench 108. Well 114 is, for example, doped with a second conductivity type opposite to the first conductivity type, type N in this example. For example, substrate 104 has a doping level in the range from 1×10¹⁶ to 1×10¹⁹ at./cm³ at the location where well 114 is formed.

As an example, well 114 is formed by ion implantation of dopant species on the side of the upper surface 104T of substrate 104 in a region symbolized, in FIG. 1, by a dotted frame 116. Well 114 for example has a thickness in the range from 50 to 500 nm.

In the example illustrated in FIGS. 1 and 2, another well 118 is formed inside of well 114. Well 118 is, in this example, located between part 108L of insulating trench 108 and part 106L of peripheral insulating trench 106. In the shown example, well 118 is separated from side walls 1080 and 106I by parts of well 114. Well 118 extends vertically across the thickness of substrate 104, from its upper surface 104T, down to a depth smaller than that of well 114. Well 118 is, for example, more heavily doped with the second conductivity type, type N in this example (N⁺), than well 114. Substrate 104 for example has, at the location where well 118 is formed, a doping level in the range from 1×10¹⁷ to 5×10²⁰ at./cm³.

In the example illustrated in FIG. 1, a conductive pad 120 is located on top of and in contact with the electrically-conductive region 106C of peripheral insulating trench 106. Conductive pad 120 enables to bias electrically-conductive region 106C. As an example, in the case where substrate 104 is of type P, the electrically-conductive region 106C of peripheral insulating trench 106 is taken to a fixed potential, for example equal to approximately 1.8 V. This tends to cause an accumulation of electrons along the side walls 106I, 106O of peripheral insulating trench 106. This accumulation of electrons especially enables to avoid for electrons photogenerated in photosensitive area 102 to be trapped at the interface between substrate 104 and peripheral insulating trench 106.

In the shown example, pixel 100 further comprises another conductive pad 122 located on top of and in contact with the electrically-conductive region 108C of the insulating trench 108 of vertical transfer gate TG. Conductive pad 122 is for example intended to bias electrically-conductive region 108C.

During a phase of exposure of pixel 100, electron-hole pairs are for example created inside of photosensitive area 102. During this phase, the electrically-conductive region 108C of insulating trench 108 is for example taken to a fixed potential, for example equal to approximately 1.8 V. During the sensor exposure phase, the application of this potential to electrically-conductive region 108C enables to form a potential barrier in a transfer region 124 (FIG. 2) located inside of vertical transfer gate TG, between photosensitive area 102 and collection area 110. In the shown example, transfer region 124 is bordered by the inner side walls 108I of the insulating trench 108 of vertical transfer gate TG and vertically extends, across the thickness of substrate 104, under collection area 110. In this example, transfer region 124 laterally extends from transfer gate TG to peripheral insulating trench 106.

In the shown example, transfer region 124 and charge collection area 110 are located vertically in line with photosensitive area 102. In other words, in top view, transfer region 124 and charge collection area 110 each have, in top view, a smaller surface area than that of photosensitive area 102 and their respective projections in the plane of photosensitive area 102 are inscribed within the surface area of this area. Further, transfer region 124 and charge collection area 110 may, in top view, be off-centered with respect to photosensitive area 102.

The presence of the potential barrier in transfer region 124 enables, during the exposure phase, to block the transfer of photogenerated holes from photosensitive area 102 to collection area 110. This potential barrier results from the presence, along the side walls 108I of insulating trench 108, of an inversion layer attracting carriers of the type opposite to the substrate, that is, electrons, in this example.

During a readout phase subsequent to the exposure phase, the electrically-conductive region 108C of insulating trench 108 is for example taken to a substantially zero potential. During the readout phase, the application of the zero potential to electrically-conductive region 108C enables to decrease, or even to remove, the potential barrier in transfer region 124 between photosensitive area 102 and collection area 110. The disappearing of the potential barrier allows, during the readout phase, a transfer of photogenerated holes from photosensitive area 102 to collection area 110.

In the shown example, pixel 100 further comprises still another conductive pad 126, located on top of and in contact with charge collection area 110. Conductive pad 126 for example enables to transfer charges accumulated in area 110 to a readout circuit, not shown, for example located on the side of the upper surface 104T of substrate 104. Conductive pad 126 is for example connected to a node for reading from pixel 100, not shown in FIGS. 1 and 2. In the example shown in FIG. 1, conductive pad 126 is located substantially at the center of the upper surface of charge collection area 110. Conductive pad 126 is in this case separated from each inner side wall 108I of insulating trench 108 by a same distance D5. As an example, distance D5 is in the order of 50 nm.

In the shown example, pixel 100 further comprises another conductive pad 128, located on top of and in contact with well 118. Conductive pad 128 for example enables to supply the electrons enabling to create the potential barrier inside of transfer region 124 during the above-described exposure phase. As an example, in the case where substrate 104 is of type P, well 118 is taken to a fixed potential, for example equal to approximately 1.5 V, via conductive pad 128.

In the shown example, insulating trenches 106 and 108 each comprise, on the side of the upper surface 104T of substrate 104, an electrically-insulating region 130 (FIG. 2) coating the upper ends of electrically-conductive and electrically-insulating regions 106C, 108C and 106S, 108S. Electrically-insulating region 130 has not been shown in FIG. 1 to avoid overloading the drawing. In this example, conductive pads 120, 122 run through electrically-insulating region 130 and respectively contact the upper surface of electrically-conductive region 106C, 108C. As a variant, the electrically-insulating region 130 of peripheral insulating trench 106 and/or that of insulating trench 108 may be omitted.

In a sensor comprising a plurality of pixels arranged in an array of rows and columns, there is designated by “pixel pitch” the center-to-center distance between two neighboring pixels in the row or column direction. The pixel pitch in the row or column direction substantially corresponds to the lateral dimension of the pixel in said direction. In the case of the sensor integrating the above-described pixels 100, the pixel pitch in the row direction and in the column direction corresponds, for example, to distance 2*(D1+D2+D3)+D4. This distance is for example in the order of 1 μm.

For certain applications, it would be desirable to be able to decrease the pixel pitch of image sensors. However, in the case of pixel 100, the pixel dimension is constrained by design rules which impose, for example, minimum values for distance D3, separating vertical transfer gate TG from peripheral insulating trench 106, and for distance D5, separating conductive pad 126 from vertical transfer gate TG. In the case of pixel 1, distance D5 directly impacts distance D4, having the lateral dimension and thus the pixel pitch depending thereon. The minimum value imposed to distance D5 for example aims at ensuring that conductive pad 126 is in contact with the upper surface of charge collection area 110 only, and that conductive pad 126 does not for example encroach upon insulating trench 108.

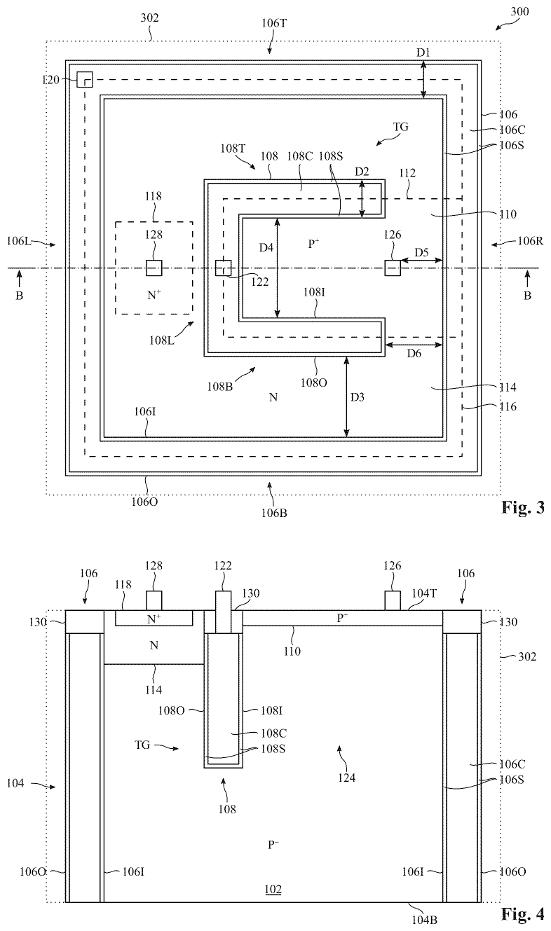

FIG. 3 is a simplified and partial top view of an example of a pixel 300 of an image sensor according to a first embodiment. FIG. 4 is a simplified and partial cross-section view of pixel 200 along plane BB of FIG. 3.

The pixel 300 of FIGS. 3 and 4 comprises elements in common with the pixel 100 of FIGS. 1 and 2. These common elements will not be detailed again hereafter. The pixel 300 of FIGS. 3 and 4 differs from the pixel 100 of FIGS. 1 and 2 in that the vertical transfer gate TG of pixel 300 comprises three parts only. In the shown example, the insulating trench 108 of pixel 300 is, as compared with the insulating trench 108 of pixel 100, devoid of the part 108R located on the side opposite to well 118. The insulating trench 108 of pixel 300 only comprises, in this example, parts 108T, 108L, and 108B. Thus, in this example, trench 108 has, in top view, a general U shape.

According to an embodiment, the charge collection area 110 of pixel 300 laterally extends from vertical transfer gate TG all the way to peripheral insulating trench 106. More specifically, in the shown example, charge collection area 110 is bordered by the inner side walls 108I of the parts 108T, 108L, and 108B of insulating trench 108 and extends all the way to the inner side wall 106I of part 106R of peripheral insulating trench 106. In this example, charge collection area 110 has, in top view, a generally rectangular shape.

In the shown example, conductive pad 126 is separated from the inner side wall 106I of part 106R of peripheral insulating trench 106 by distance D5. Pad 126 is further, in this example, separated from the inner side wall 108I of part 108L of insulating trench 108 by a distance greater than distance D5.

In the example illustrated in FIG. 4, the parts 108T and 108B of trench 108 are respectively separated the parts 106T and 106B of trench 106 by distance D3. Further, in this example, the ends of parts 108T and 108B closest to part 106R are separated from part 106R by a distance D6. Distance D6 is for example shorter than distance D3. As an example, distance D6 is in the range from 20 to 300 nm.

As an example, in the case where substrate 104 is of type P, the electrically-conductive region 106C of peripheral insulating trench 106 is taken to a fixed potential, for example equal to approximately 1.8 V. This tends to cause an accumulation of electrons along the side walls 106I, 106O of peripheral insulating trench 106. This electron accumulation particularly enables to avoid for electrons photogenerated in photosensitive area 102 to be trapped at the interface between substrate 104 and peripheral insulating trench 106. Advantage is here taken of the potential applied to the electrically-conductive region 106C of peripheral insulating trench 106 to switch, according to the potential applied to vertical transfer gate TG, transfer region 124 between a blocked state and a conductive state. Unlike the example in FIGS. 1 and 2, the pixel 300 of FIGS. 3 and 4 jointly uses vertical transfer gate TG and peripheral insulating trench to control the blocking or unblocking of transfer region 124.

An advantage of the embodiment of pixel 300 discussed in relation with FIGS. 3 and 4 lies in the fact that the geometry of vertical transfer gate TG generally allows to release the dimensional constraints imposed by the design rules. Pixel 300 particularly enables to advantageously decrease the constraints of positioning of conductive pad 126 with respect to trenches 106 and 108. The geometry of the vertical transfer gate TG of pixel 300 more precisely allows a greater latitude in the positioning of conductive pad 126 on area 110, for example along a horizontal axis parallel to cutting plane BB.

This enables, as illustrated in FIGS. 3 and 4, to decrease the lateral dimensions of pixel 300 as compared with pixel 100, having its outline symbolized in FIGS. 3 and 4 by a dotted frame 302. As an example, pixel 300 has lateral dimensions in the order of 0.8 μm.

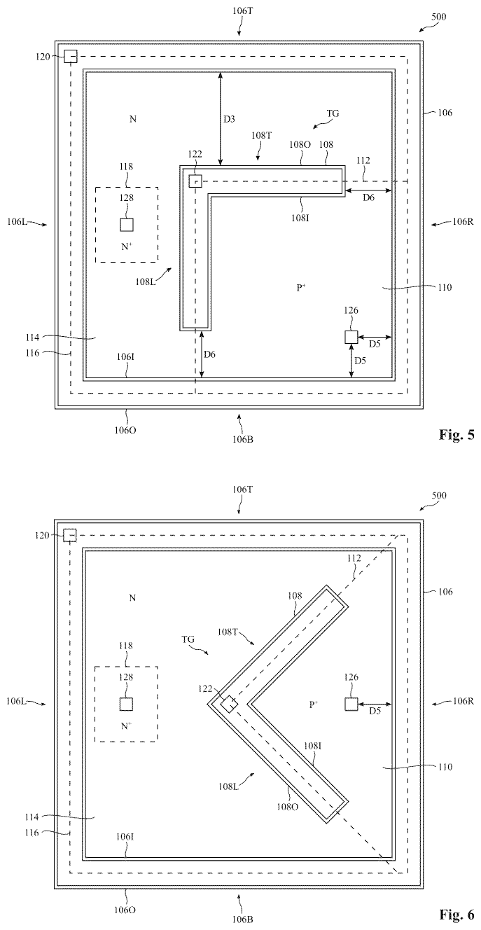

FIG. 5 is a simplified and partial top view of an example of a pixel 500 of an image sensor according to a second embodiment.

The pixel 500 of FIG. 5 has elements in common with the pixel 300 of FIGS. 3 and 4. These common elements will not be detailed again hereafter. The pixel 500 of FIG. 5 differs from the pixel 300 of FIGS. 3 and 4 in that the vertical transfer gate TG of pixel 500 comprises two parts only. In the shown example, the insulating trench 108 of pixel 500 is, as compared with the insulating trench 108 of pixel 300, devoid of part 108B. The insulating trench 108 of pixel 500 only comprises, in this example, parts 108T and 108L. Thus, in this example, trench 108 has, in top view, a general L shape.

In the shown example, charge collection area 110 is bordered by the inner side walls 108I of the parts 108T and 108L of insulating trench 108, and extends all the way to the inner side wall 106I of the parts 106R and 106B of peripheral insulating trench 106. In this example, charge collection area 110 has, in top view, a generally square or rectangular shape.

In the example shown, conductive pad 126 is separated from the inner side walls 106I of the parts 106R and 106B of peripheral insulating trench 106 by distance D5. Pad 126 is further, in this example, separated from the inner side walls 108I of the parts 108L and 108T of insulating trench 108 by a distance greater than distance D5.

As compared with the pixel 300 of FIGS. 3 and 4, the geometry of the vertical transfer gate TG of pixel 500 advantageously allows an even greater freedom of positioning of conductive pad 126. This enables to further decrease the lateral dimensions of pixel 500 as compared with pixel 300.

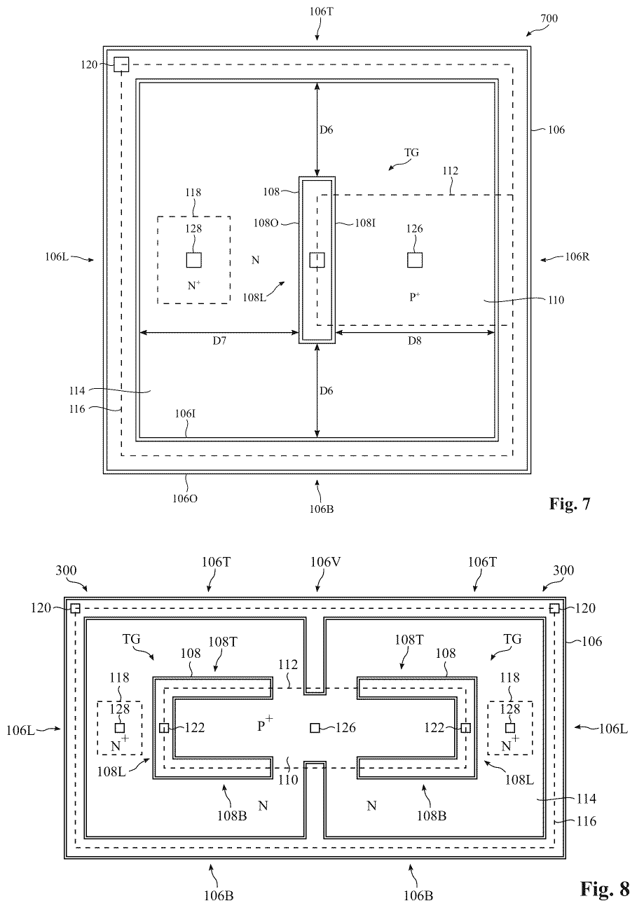

FIG. 6 is a simplified and partial top view of a variant of the pixel 500 of FIG. 5.

In this variant, the vertical transfer gate TG of pixel 500 is rotated by an angle of approximately 45° with respect to FIG. 5. In the shown example, the charge collection area 110 has a substantially triangular shape, having a side delimited by the inner side wall 106I of part 106R of peripheral insulating trench 106, and having two other sides delimited by the inner side walls 108I of the parts 108T and 108L of insulating trench 108.

FIG. 7 is a simplified and partial top view of an example of a pixel 700 of an image sensor according to a third embodiment.

The pixel 700 of FIG. 7 has elements in common with the pixel 500 of FIG. 5. These common elements will not be detailed again hereafter. The pixel 700 of FIG. 7 differs from the pixel 500 of FIG. 5 in that the vertical transfer gate TG of pixel 700 comprises a single part. In the shown example, the insulating trench 108 of pixel 700 is, as compared with the insulating trench 108 of pixel 500, devoid of part 108T. The insulating trench 108 of pixel 700 only comprises, in this example, part 108L. Thus, in this example, insulating trench 108 has, in top view, an I shape (that is, in top view, the shape of a vertical bar).

In the shown example, charge collection area 110 laterally extends between the inner side wall 108I of the part 108L of insulating trench 108 and extends all the way to the inner side wall 106I of part 106R of peripheral insulating trench 106. In this example, charge collection area 110 has, in top view, a generally rectangular shape.

In the shown example, conductive pad 126 is separated from the inner side wall 106I of the part 106R of peripheral insulating trench 106 by a distance greater than distance D5. Pad 126 is further, in this example, separated from the inner side wall 108I of the part 108L of insulating trench 108 by a distance greater than distance D5.

In this example, the part 108L of the peripheral insulating trench is separated from part 106L of peripheral insulating trench 106 by a distance D7 and from part 106R of trench 106 by a distance D8. As an example, distance D7 is in the range from 50 to 500 nm and distance D8 is in the range from 50 to 800 nm.

FIG. 8 is a simplified and partial top view of an arrangement of two pixels 300 according to the first embodiment.

In the shown example, the two pixels 300 are juxtaposed so that they share a common vertical part 106V of peripheral insulating trench 106. In the orientation of FIG. 8, the left-hand pixel 300 is for example symmetrical to the right-hand pixel 300 with respect to vertical part 106V. This enables to decrease the surface area occupied by the image sensor pixels. In the orientation of FIG. 8, with reference to the pixel 300 of FIG. 3, part 106V corresponds to part 106R of the left-hand pixel and to part 106R of the right-hand pixel.

In the example illustrated in FIG. 8, part 106V of peripheral insulating trench 106 is discontinuous. In this example, part 106V more precisely has an upper portion, located on the side of the parts 106T of pixels 300, and a lower portion, located on the side of the parts 106B of pixels 300. The lower and upper portions of parts 106V are separated by a part of charge collection area 110. In this example, charge collection area 110 extends from the vertical transfer gate TG of each pixel 300 of the arrangement illustrated in FIG. 8 to the common vertical part 106V of peripheral insulating trench 106. Charge collection area 110 also extends into the area of interruption of part 106V of peripheral insulating trench 106.

The two pixels 300 of the arrangement comprise, for example, a single common conductive pad 126. The common conductive pad 126 is for example located in a region of area 110 located between the upper and lower portions of part 106V of peripheral insulating trench 106 (that is, in front of the area of interruption of part 106V of insulating trench 106).

In the arrangement of FIG. 8, the vertical transfer gates TG of the two pixels 300 are for example alternately controlled in order to transfer, to pad 126, the charges photogenerated in the photosensitive area 102 of one of pixels 300, and then the charges photogenerated in the photosensitive area 102 of the other pixel 300 (sequential transfer).

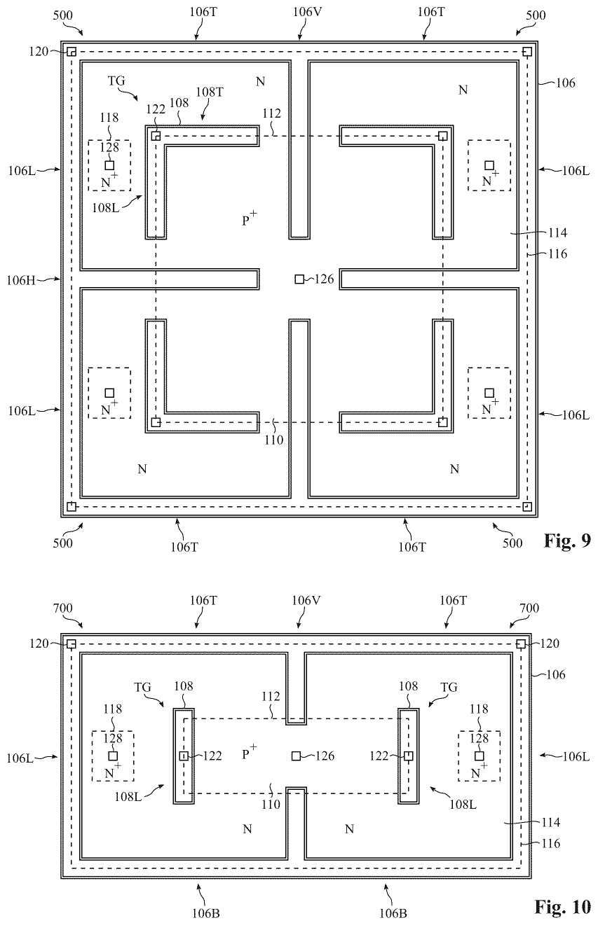

FIG. 9 is a simplified and partial top view of an arrangement of four pixels 500 according to the second embodiment.

In the shown example, the four pixels 500 are juxtaposed so that they share common vertical and horizontal parts 106V and 106H of peripheral insulating trench 106. In the orientation of FIG. 9, the pixels 500 located on the left-hand side are for example symmetrical to the pixels 500 located on the right-hand side with respect to vertical part 106V. Further, the pixels 500 located at the top are for example symmetrical to the pixels 500 located at the bottom with respect to horizontal part 106H. This enables to decrease the surface area occupied by the pixels 500 of the image sensor. In the orientation of FIG. 9, referring to the pixel 500 of FIG. 5, part 106V corresponds to the parts 106R of the left-hand pixels and to the parts 106R of the right-hand pixels. Further, part 106H corresponds to the parts 106B of the top pixels and to the parts 106B of the bottom pixels.

In the example illustrated in FIG. 9, the parts 106V and 106H of peripheral insulating trench 106 are discontinuous at the center of the arrangement formed by the four pixels 500. In this example, charge collection area 110 extends between the vertical transfer gate TG of each pixel 500 of the arrangement illustrated in FIG. 9 and the common portions 106V and 106H of peripheral insulating trench 106. Charge collection area 110 further extends across the area of interruption of the parts 106V and 106H of peripheral insulating trench 106. The four pixels 500 of the arrangement comprise, for example, a single common conductive pad 126. Common conductive pad 126 is for example located at the center of the arrangement (that is, in front of the area of interruption of the parts 106V and 106H of insulating trench 106).

FIG. 10 is a simplified and partial top view of an arrangement of two pixels 700 according to the third embodiment.

The arrangement of FIG. 10 is similar to the arrangement previously described in relation with FIG. 8. In the arrangement shown in FIG. 10, charge collection area 110 extends between the two parts 108L of the insulating trenches 108 of the vertical transfer gates TG of pixels 700.

FIG. 11 is a simplified and partial top view of an arrangement of two pixels according to the variant of FIG. 6.

The arrangement of FIG. 11 is similar to the arrangement previously described in relation with FIG. 8. In the arrangement of FIG. 11, charge collection area 110 extends between the two vertical transfer gates TG of pixels 500.

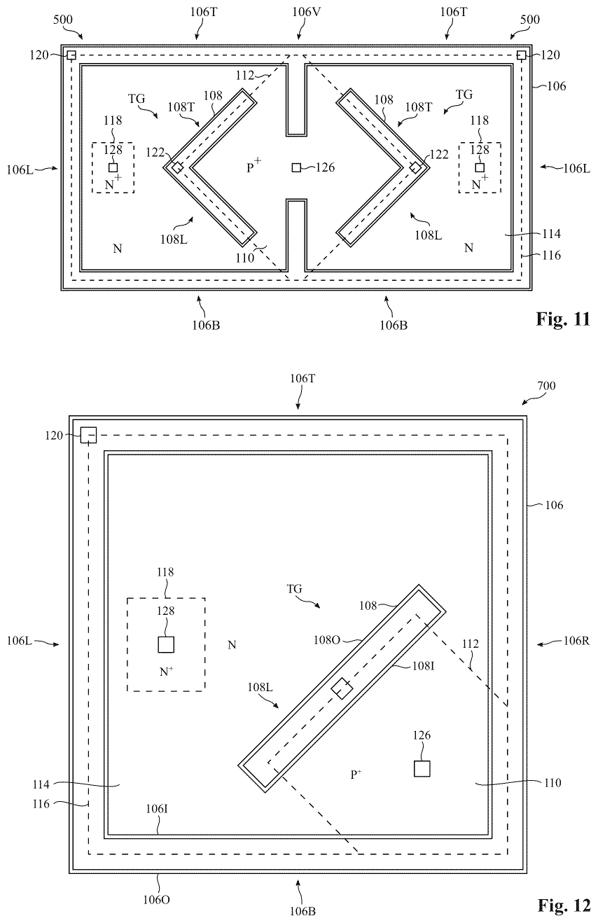

FIG. 12 is a simplified and partial top view of a variant of the pixel of FIG. 7.

In this variant, the vertical transfer gate TG of pixel 700 is rotated by an angle of approximately 45°, clockwise, with respect to FIG. 7. In the shown example, charge collection area 110 is delimited by the inner side wall 106I of part 106R of peripheral insulating trench 106 and by the inner side wall 108I of part 108L of insulating trench 108.

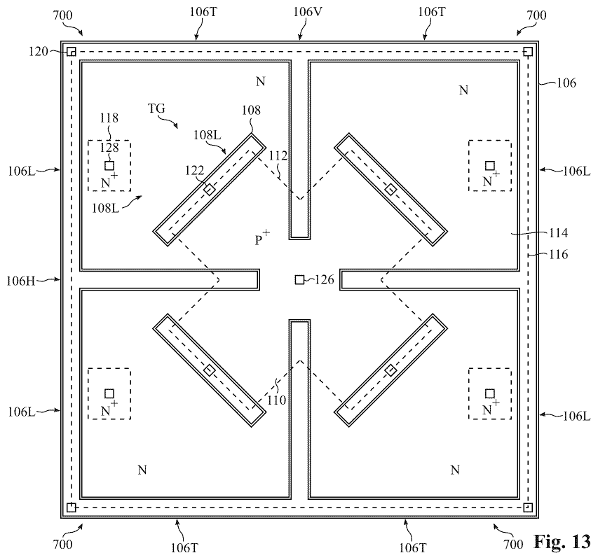

FIG. 13 is a simplified and partial top view of an arrangement of four pixels according to the variant of FIG. 12.

The arrangement of FIG. 13 is similar to the arrangement previously described in relation with FIG. 9. In the arrangement of FIG. 13, the vertical transfer gates TG of two diagonally-opposite pixels 700 are parallel to each other.

Various embodiments and variants have been described. Those skilled in the art will understand that certain features of these various embodiments and variants may be combined, and other variants will occur to those skilled in the art. In particular, although pixels 300, 500, and 700 having a square shape have been shown, the described embodiments are not limited to this geometry. In particular, those skilled in the art are especially capable of transposing the described embodiments to pixels having a rectangular shape.

Further, it should be noted that in the above-described examples, all the conductivity types of the semiconductor regions may be inverted.

Finally, the practical implementation of the described embodiments and variants is within the abilities of those skilled in the art based on the functional indications given hereabove. In particular, those skilled in the art are capable of adjusting the values of distances D1 to D8 according to the targeted application.

1. Image sensor comprising a plurality of pixels formed inside and on top of a semiconductor substrate, each pixel comprising:
a photosensitive area formed in the semiconductor substrate;
a peripheral insulating trench vertically extending across the semiconductor substrate, from an upper surface of the semiconductor substrate, and laterally delimiting the photosensitive area;
a charge collection area located vertically in line with the photosensitive area;
a transfer region located in the semiconductor substrate and doped with the same conductivity type as the photosensitive area, vertically extending between the charge collection area and the photosensitive area; and
a transfer gate vertically extending across the semiconductor substrate, from the upper surface of the semiconductor substrate, deeper than the charge collection area,
wherein the charge collection area and the transfer region laterally extend from the transfer gate all the way to the peripheral insulating trench.

2. Sensor according to claim 1, wherein the charge collection area has the same conductivity type and a higher doping level than the transfer region.

3. Sensor according to claim 1, wherein the transfer region has a same doping level as the photosensitive area.

4. Sensor according to claim 1, wherein the transfer gate of each pixel has, in top view, a U shape.

5. Sensor according to claim 1, wherein the transfer gate of each pixel has, in top view, an L shape.

6. Sensor according to claim 1, wherein the transfer gate of each pixel has, in top view, an I shape.

7. Sensor according to claim 1, wherein the transfer gate of each pixel comprises a capacitive insulating trench comprising an electrically-conductive region insulated from the semiconductor substrate.

8. Sensor according to claim 7, wherein the electrically-conductive region is made of a metal or of a metal alloy.

9. Sensor according to claim 7, wherein the electrically-conductive region is made of polysilicon.

10. Sensor according to claim 1, wherein the transfer gate is separated from the peripheral insulating trench by a non-zero distance.

11. Sensor according to claim 1, further comprising a conductive pad located on top of and in contact with the charge collection area, at a distance from the transfer gate and from the peripheral insulating trench.

12. Sensor according to claim 11, wherein the charge collection area and the conductive pad are shared between two neighboring pixels.

13. Sensor according to claim 11, wherein the charge collection area and the conductive pad are shared between four neighboring pixels.

14. Sensor according to claim 13, wherein the transfer gate has, in top view, an I shape, the transfer gates of two diagonally-opposite pixels being parallel to each other.

15. CVS Sensor according to claim 1, wherein the peripheral insulating trench comprises a conductive region insulated from the substrate.

16. Sensor according to claim 1, further comprising a control circuit configured to alternately apply, to the transfer gate:
a first potential adapted to blocking a charge transfer from the photosensitive area to the charge collection area; and
a second potential, different from the first potential, adapted to allowing a charge transfer from the photosensitive area to the charge collection area.
